(19) United States
(12) Patent Application Publication
(10) Pub. No.: US 2005/0133897 A1
(43) Pub. Date: Jun. 23, 2005

(54) Stack package with improved heat radiation and module having the stack package mounted thereon

(76) Inventors: Joong-Hyun Baek, Gyeonggi-do (KR); Young-Hee Song, Gyeonggi-do (KR); Sang-Wook Park, Gyeonggi-do (KR)

Correspondence Address: MARGER JOHNSON & MCCOLLOM, P.C., 1030 SW MORRISON STREET, PORTLAND, OR, 97205, US

(21) Appl. No.: 11/009,169

(22) Filed: Dec. 10, 2004

(30) Foreign Application Priority Data
Dec. 17, 2003 (KR) 2003-92706

(51) Int. Cl. H01L 23/48

(52) U.S. Cl. 257/686; 257/784; 257/787

(57) ABSTRACT

A stack package with improved heat radiation capability and a module having the stack package mounted thereon are provided in which the back surfaces of first and second chips are exposed through the bottom and top surfaces of the stack package, allowing improved heat radiation capability as well as reduced thickness of the stack package. A heat sink may be attached to the stack package for increasing heat radiation capability. A solder bonding portion may be formed between the stack package and a module substrate, establishing good solder bondability between the stack package and the module substrate.

### RELATED APPLICATION

This U.S. non-provisional application claims priority under 35 U.S.C. §119 from Korean Patent Application No. 2003-92706 filed on Dec. 17, 2003, the entire contents of which are hereby incorporated by reference.

### BACKGROUND OF THE INVENTION

1. Field of the Invention

The present invention relates to a stack package with improved heat radiation capability and a module having the stack package mounted thereon.

2. Description of the Related Art

Semiconductor products that are lighter, smaller and thinner, and include a great capacity of total memory continue to be desirable. In order to increase the memory capacity of semiconductor products while decreasing their size, technology that can arrange semiconductor memory chips more densely per area of semiconductor substrate used is necessary. One solution has been 3-D type semiconductor packaging technologies based on stacking semiconductor chips.

Examples of 3-D stack chip packages include a package including a plurality of semiconductor chips stacked on each other, therefore achieving denser, more compact semiconductor packages. Unfortunately, 3-D type semiconductor packaging technologies based on chip stacking have negatively impacted production rates. For example, faulty chips can dramatically impact production rates because a single faulty chip among a stack of semiconductor chips will cause the whole stack of semiconductor chips to be faulty and non-repairable. Chips are typically unable to be validated until they are included in a package.

One solution to the faulty stack problem has been to stack packages instead of chips. Although a stack of packages is thicker than a stack of chips since each chip includes its own package, a stack of packages has the advantage that each package may be individually validated, thus avoiding the reliability and production rate problems caused by chip stacking.

FIG. 1 is a cross-sectional view of a conventional stack package 10 based on stacking packages. Referring to FIG. 1, the stack package 10 comprises two semiconductor packages 20 with a flexible connection substrate 40 interposed there between.

The semiconductor package 20 is a typical thin small outline package (TSOP) type semiconductor package. Inner leads 23 of the semiconductor package 20 are arranged on the active surface of a semiconductor chip 21 having center pads 22, namely a lead on chip (LOC) type center pads. The inner leads 23 are electrically connected to the center pads 22 by bonding wires 24. A molding resin encapsulates the semiconductor chip 21, inner leads 23 and bonding wires 24 to form a package body 26. Outer leads 25, connected to the inner leads 23, extend from the package body 26 and are bent to form a so-called gull wing shape. The lower semiconductor package is herein referred to as a first package 20a. The upper semiconductor package is herein referred to as a second package 20b.

The flexible connection substrate 40 is interposed between the first package 20a and the second package 20b. The flexible connection substrate 40 has a double-sided adhesive property. A connection lead 43 of the flexible connection substrate 40 electrically connects outer leads 25a of the first package 20a with outer leads 25b of the second package 20b. The thickness of each of the first and second packages 20a and 20b is approximately 1.2 mm. The thickness of the flexible connection substrate 40 is approximately 0.2 mm. The thickness of the stack package 10 ranges from approximately between 2.4 mm and 2.6 mm.

In exemplary embodiments of the stack package 10, the first and second packages 20a and 20b each have the semiconductor chip 21 embedded in the package body 26. The package body 26 has low heat conductivity. Therefore, the heat generated by the semiconductor chips is insulated by the package body 26.

Stack packages 10 are typically attached to a module 50 as shown in FIG. 2. The stack packages 10 are coupled to each other by a slot 59 of a motherboard 58. The module 50 comprises a module substrate 51, on which stack packages 10 are mounted on two surfaces of the module 50 at a predetermined interval. The thickness of the module substrate 51 is approximately 1.27 mm. The space (t1) between the slots 59 defined by the motherboard 58 ranges between 9.5 mm and 10 mm. Therefore, the space (t2) between the modules 50 ranges between 3.4 mm and 3.9 mm. The narrower the space (t2) is, the less air will reach the stack packages 10, and thus less thermal radiation of the heat generated by the semiconductor chips will result.

Further, an external heat sink 57 may be installed by a user or manufacturer as shown in FIG. 3 in an attempt to increase thermal radiation from the semiconductor chips. Unfortunately, the heat radiation capability of the heat sink 57 may be hindered by a reduced space (t3), and thus reduced air flow between the modules 50. Moreover, the heat sink 57 is typically attached to the top surface of the package body 26 that has low heat conductivity, thus further limiting the effect of the heat sink 57.

Another problem related to the heat caused by the semiconductor chips and the difficulty in radiating the heat away from the semiconductor chips, is that the bond between the stack package 10 and the module substrate 51 may be weakened by thermal stress. For example, the outer leads 25a of the stack package 10 are solder-bonded to substrate pads (not shown) of the module substrate 51. Thermal stresses which may result from the difference of the coefficients of thermal expansion (CTE) of the stack package 10 and the module substrate 51 may be concentrated on a solder-bonded portion of the stack package 10 and the module substrate 51, thus reducing the solder bondability.

Embodiments of the invention address these and other limitations in the prior art.

### SUMMARY OF THE INVENTION

An exemplary embodiment of the present invention is directed to a stack package with improved heat radiation capability.

Another exemplary embodiment of the present invention is directed to a thin stack package.

Yet another exemplary embodiment of the present invention is directed to a stack package that will prevent deterioration of the flow of air between modules.

Still another exemplary embodiment of the present invention is directed to a stack package with improved heat radiation through a heat sink.

A further exemplary embodiment of the present invention is directed to a stack package with improved heat radiation through a bottom surface thereof.

Yet a further exemplary embodiment of the present invention is directed to a module with improved solder bondability.

According to at least one exemplary embodiment of the present invention, the stack package comprises a first package, a second package and a flexible connection substrate. The first package has a first package body having a top surface and a bottom surface. A first chip has an active surface and a back surface. The first chip is embedded in the first package body such that the back surface of the first chip is exposed through the bottom surface of the first package body. First outer leads extend from the first package body and are electrically connected to the first chip. The second package, mounted on the first package, has a second package body having a top surface and a bottom surface. A second chip has an active surface and a back surface. The second chip is embedded in the second package body such that the back surface of the second chip is exposed through the top surface of the second package body. Second outer leads extend to the second package body and are electrically connected to the second chip. The flexible connection substrate is interposed between the first package and the second package and electrically connects the first package with the second package.

According to another exemplary embodiment of the present invention, a module comprises a module substrate having the above described stack packages mounted thereon.

### BRIEF DESCRIPTION OF THE DRAWINGS

Exemplary embodiments of the present invention will be described with reference to the accompanying drawings, wherein like reference numerals designate like structural elements, and, in which:

FIG. 1 is a cross-sectional view of a conventional stack package.

FIG. 2 is a plane view of the conventional stack package of FIG. 1.

FIG. 3 is a plane view of modules including the conventional stack package of FIG. 1.

FIG. 4 is a cross-sectional view of a stack package in accordance with exemplary embodiments of the present invention.

FIG. 5 is a plane view of wire-bonding configuration.

FIG. 6 is a plane view of wire-bonding configuration FIG. 7 is a plane view of a module in accordance with a first embodiment of the present invention.

FIG. 8 is a cross-sectional view taken along the line of VIII-VIII of FIG. 7.

FIG. 9 is a cross-sectional view of a module in accordance with a second embodiment of the present invention.

FIG. 10 is a cross-sectional view of a module in accordance with a third embodiment of the present invention.

FIG. 11 is an enlarged view of section A of FIG. 10.

FIG. 12 is a bottom view of a first chip of FIG. 10.

FIG. 13 is a cross-sectional view of a module in accordance with a fourth embodiment of the present invention.

### DETAILED DESCRIPTION OF THE PREFERRED EMBODIMENTS

Exemplary embodiments of the present invention will be described below with reference to the accompanying drawings. It will be understood that the depicted elements may be simplified and/or merely exemplary, and may not necessarily be drawn to scale. It will be understood that when an element such as a layer, region or substrate is referred to as being “on” or “onto” another element, it can be directly on the other element or intervening elements may also be present. Additionally, the layer, region or substrate could be partially within or partially embedded in another element.

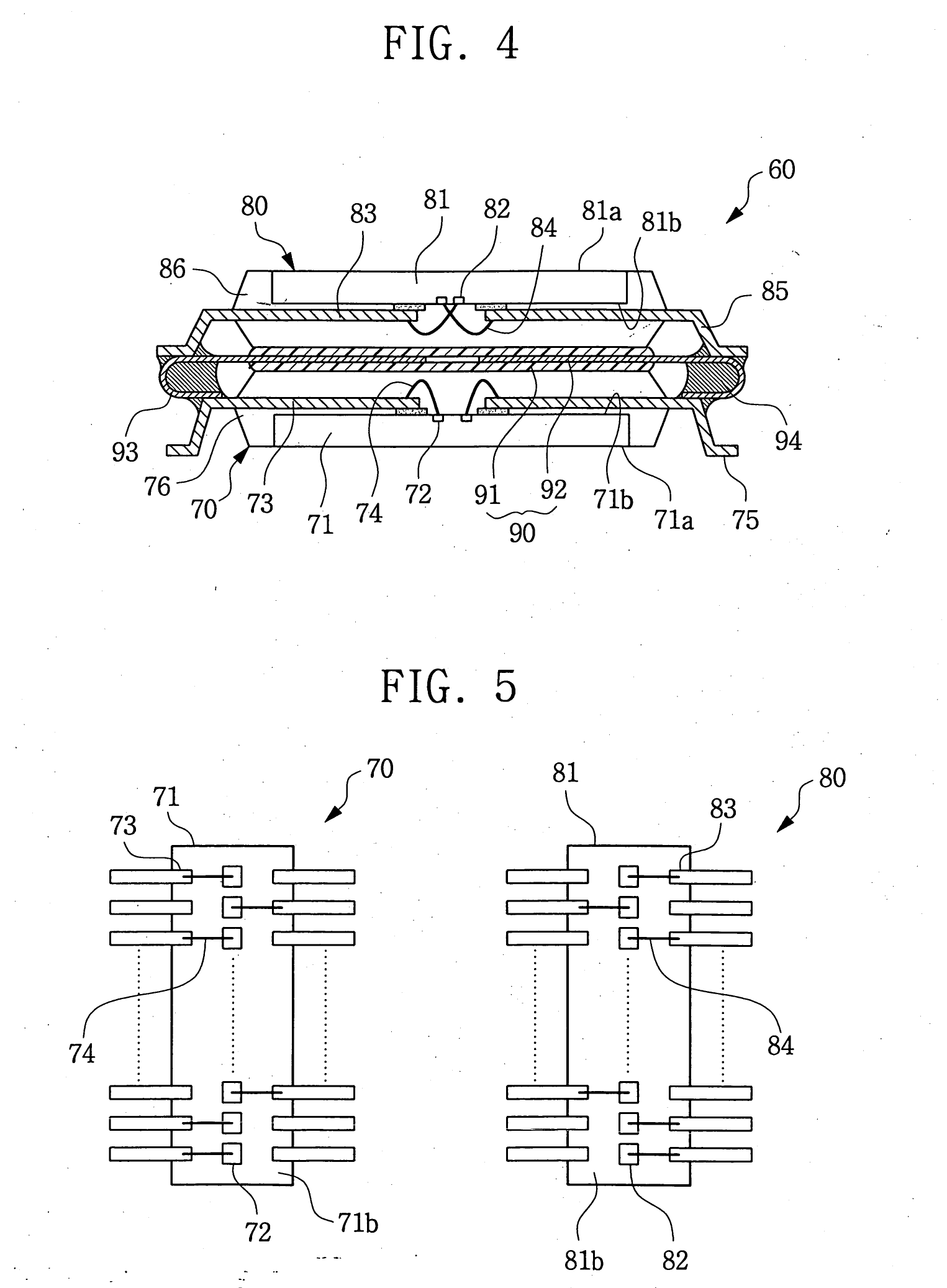

FIG. 4 is a cross-sectional view of a stack package in accordance with an embodiment of the present invention. Referring to FIG. 4, a stack package 60 comprises a first package 70 and a second package 80. The second package 80 is vertically stacked on the first package 70. A flexible connection substrate 90 is interposed between the first package 70 and the second package 80. The top surface of the first package 70 is attached to the bottom surface of the flexible connection substrate 90. The first package 70 has a first chip 71 disposed to the bottom surface thereof. The back surface 71a of the first chip 71 is exposed. The bottom surface of the second package 80 is attached to the top surface of the flexible connection substrate 90. The second package 80 has a second chip 81 disposed to the top surface thereof. The back surface 81a of the second chip 81 is exposed. The back surfaces 71a and 81a of the first and second chips 71 and 81 are exposed through the bottom and top surfaces of the stack package 60, respectively. This structure may allow better heat radiation capability than a conventional stack package.

The first package 70 also includes a first package body 76 and first outer leads 75. The first chip 71 is embedded in the first package body 76 such that the back surface 71a of the first chip 71 is exposed through the bottom surface of the first package body 76. The outer leads 75 protrude from the first package body 76 and are electrically connected with the first chip 71. Specifically, the first chip 71 is a center pad type semiconductor chip in which a plurality of first center pads 72 are arranged along the central line of the active surface 71b. First inner leads 73 are arranged at opposing edges of the active surface 71b of the first chip 71, for example in a lead on chip (LOC) type configuration. First bonding wires 74 electrically connect the first center pads 72 with the first inner leads 73. A liquid molding resin encapsulates the first chip 71, the first inner leads 73 and the first bonding wires 74 to protect them from the external environment, to form the first package body 76. The first package body 76 is formed such that the back surface 71a of the first chip 71 is exposed through the bottom surface of the first package body 76. The first outer leads 75 are connected to the corresponding first inner leads 73. The first outer leads 75 extending from the first package body 76 are bent toward the bottom surface of the first package body 76, for example, forming a gull wing type semiconductor device.

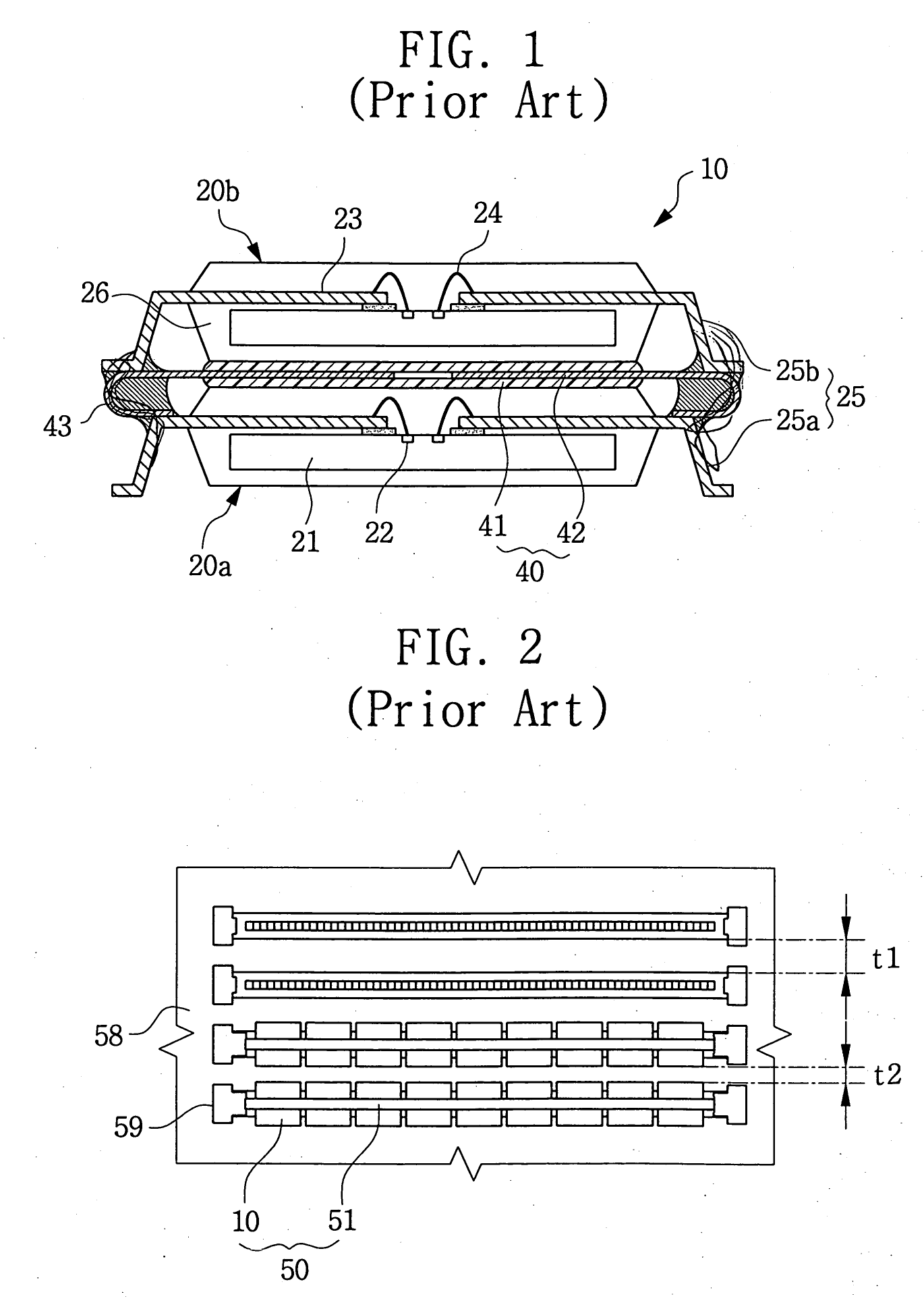

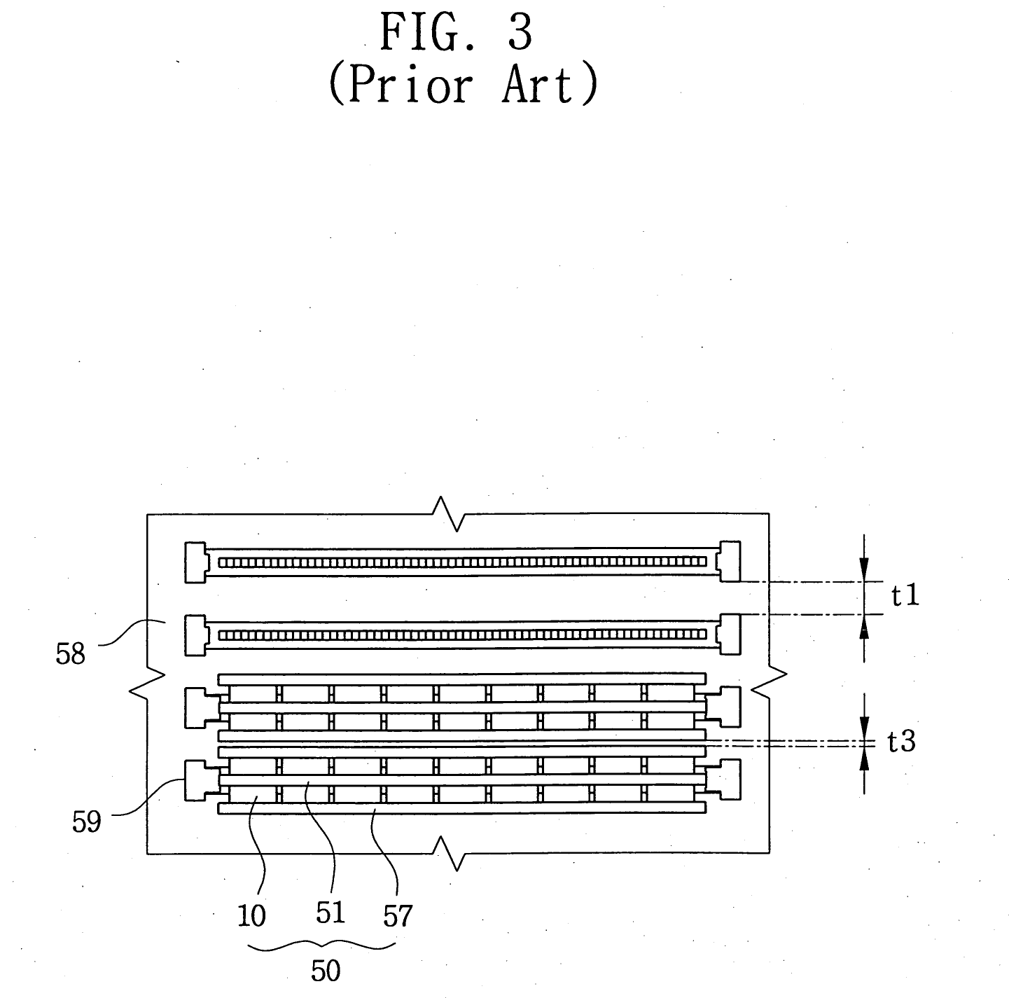

The semiconductor package of the present invention is thinner than a conventional thin small outline package (TSOP) type semiconductor package 20 shown in FIG. 1. The thickness of the first package 70 can be reduced by the thickness of a portion conventionally formed below the first chip 71. For example, the thickness of the typical TSOP type semiconductor package is about 1.2 mm, while the thickness of the first package 70 is 0.8 mm or less. Thus, in addition to the first chip 71 radiating more heat due to the lack of a first package body covering and insulating the back of the first chip 71, the second chip 81 will radiate more heat than a conventional package when installed in a motherboard due to the fact that a space t2 between one module and another will be greater. Not only does this increased space t2 allow for better heat radiation through air, the increased space allows for a heat sink to more effectively radiate heat from the second chip 81.

The second package 80, stacked on the first package 70, includes a second package body 86 and second outer leads 85. The second chip 81 is embedded in the second package body 86 such that the back surface 81a of the second chip 81 is exposed through the top surface of the second package body 86. The outer leads 85 protrude from the second package body 86 and are electrically connected with the second chip 81. Specifically, the second chip 81 is a center pad type semiconductor chip in which a plurality of second center pads 82 are arranged along the central line of the active surface 81b. Second inner leads 83 are arranged at opposing edges of the active surface 81b of the second chip 81. Second bonding wires 84 electrically connect the second center pads 82 with the second inner leads 83. A liquid molding resin encapsulates the second chip 81, the second inner leads 83 and the second bonding wires 84 to protect them from the external environment, to form the second package body 86. The second package body 86 is formed such that the back surface 81a of the second chip 81 is exposed through the top surface of the second package body 86. The second outer leads 85 are connected to the corresponding second inner leads 83. The second outer leads 85 extending from the second package body 86, are bent toward the bottom surface of the second package body 86, for example, forming a gull wing type semiconductor device.

Similarly, the thickness of the second package 80 of this embodiment can be reduced by the thickness of a portion conventionally formed on the back of the second chip 81. The structure of the second chip 81 having exposed back surface 81a can thus more effectively radiate heat.

When stacked, the first package 70 and the second package 80 have a mirror type configuration. In this configuration, the back surface 71a of the first chip 71 is exposed through the bottom surface of the stack package 60. The back surface 81a of the second chip 81 is exposed through the top surface of the stack package 60. Therefore, the efficiency of heat radiation of the stack package 60 may be increased by exposing the back portions of both semiconductor chips.

The flexible connection substrate 90 includes a tape member 91 and a wiring pattern 92. The tape member 91 has a double-sided adhesive property for attachment of the first and second packages 70 and 80 to both sides of the flexible connection substrate 90. The wiring pattern 92 is disposed within the tape member 91. The wiring pattern 92 extends from the tape member 91 and includes a connection lead 93 connecting the first outer lead 75 with the second outer lead 85. The connection lead 93 is located on the top end of the first outer lead 75 and the bottom end of the second outer lead 85. The connection lead 93 is bent in the shape of a U, for example “⊃” and “⊂”. Reference numeral 94 is a bonding member 94 such as solder.

Referring to FIG. 5, if the first chip 71 is the same as the second chip 81, for example memory chips having the same capacity, wire-bonding of the first center pads 72 is symmetrical with respect to a horizontal plane defined as a plane parallel to the flexible connection substrate 90 to wire-bonding of the second center pads 82. Because the stack of the first and second packages 70 and 80 has a mirror type configuration with respect to each other, wire-bonding of the second package 80 is made symmetrical to that of the first package 70 so as to connect the first outer leads 75 with the corresponding second outer leads 85. Thus, when the first and second center pads 72 and 82 are arranged according to a center line on the active surfaces 71b and 81b of the first and second chips 71 and 81, respectively, the first and second bonding wires 74 and 84 are horizontally symmetrical.

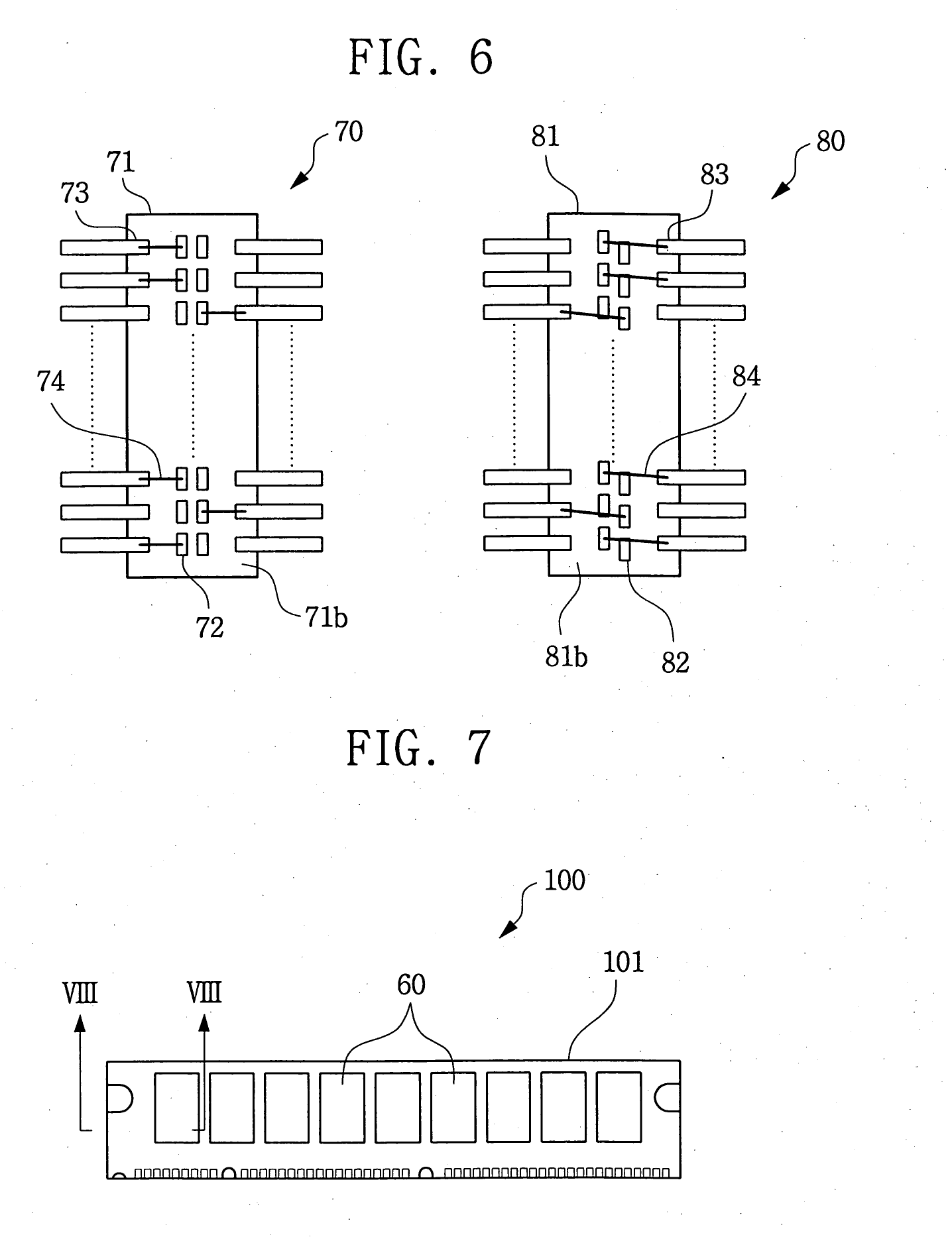

Referring to FIG. 6, when the first and second center pads 72 and 82 are arranged in two lines on the active surfaces 71b and 81b of the first and second chips 71 and 81, respectively, the first and second bonding wires 74 and 84 are nearly horizontally symmetrical. The wires are only nearly horizontally symmetrical because the wire-bonding of the second center pads 82 is cross-bonding. If the second center pads 82 are arranged in a straight row formation as the first center pads 72, short circuits may be generated between the second bonding wires 84. Thus, it is preferable that the second center pads 82 are arranged in an offset row formation.

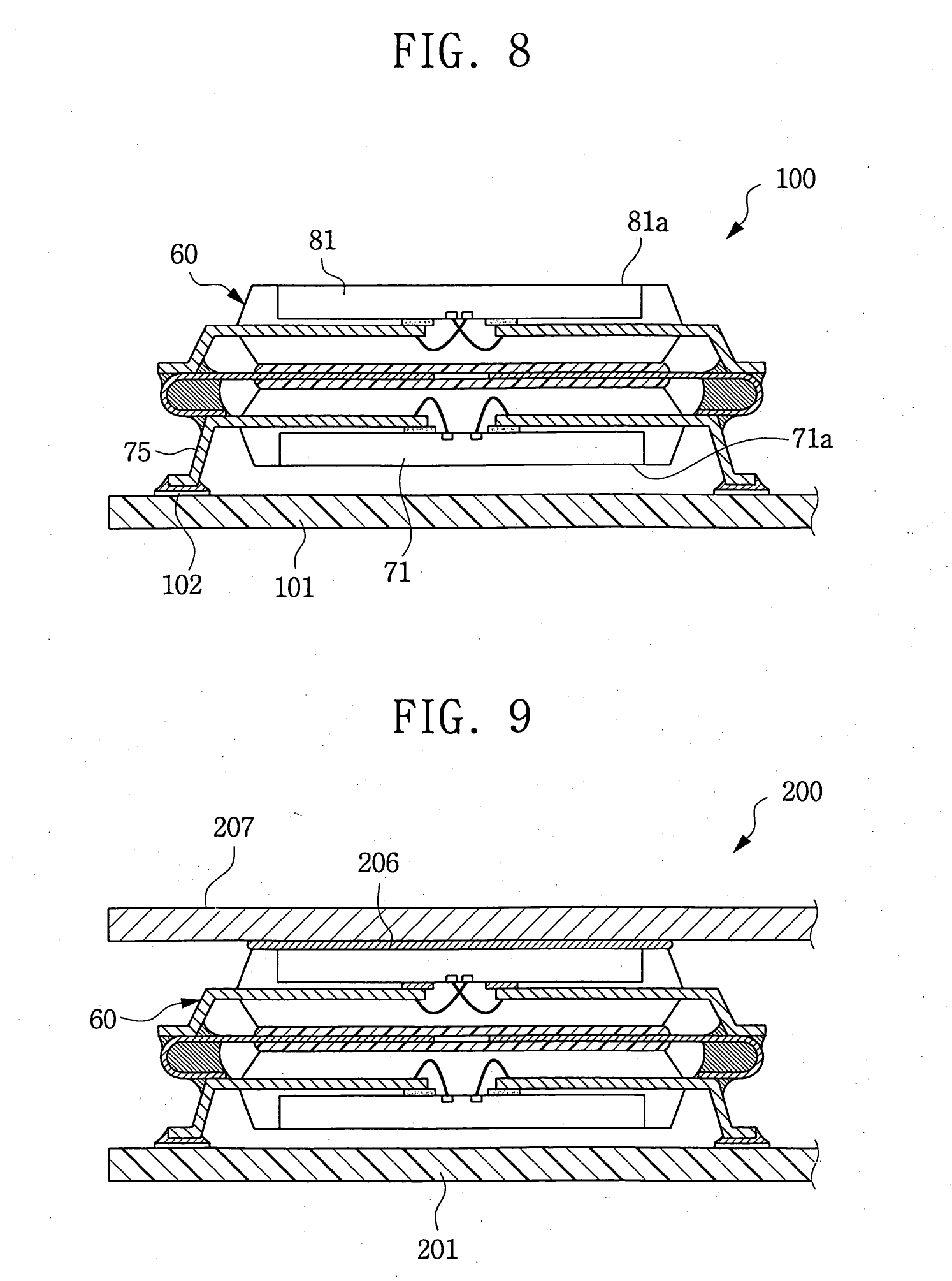

FIG. 7 is a plane view of a module 100 in accordance with a first embodiment of the present invention, in which the stack packages 60 of FIG. 4 are mounted on a module substrate 101. FIG. 8 is a cross-sectional view taken along the line of VIII-VIII of FIG. 7.

Referring to FIGS. 7 and 8, the module 100 comprises the module substrate 101. FIG. 8 is a cross-sectional view taken along the line of VIII-VIII of FIG. 7.

Referring to FIGS. 7 and 8, the module 100 comprises the module substrate 101, on one surface of which a plurality of stack packages 60 are mounted at a predetermined interval. The back surface 71a of the first chip 71 is exposed through the bottom surface of the stack package 60. The back surface 81a of the second chip 81 is exposed through the top surface of the stack package 60. Therefore, heat which the first and second chips 71 and 81 may generate during operation of the module 100 will be radiated effectively through the top and bottom surfaces of the stack package 60.

Although this embodiment shows the stack packages 60 mounted on one surface of the module substrate 101, the stack packages may of course be mounted on both surfaces of the module substrate.

FIG. 9 is a cross-sectional view of a module 200 in accordance with a second embodiment of the present invention, in which a heat sink 207 is attached to the stack package 60 of FIG. 4 mounted on a module substrate 201. Referring to FIG. 9, the module 200 comprises the heat sink 207 attached to the top surface of the stack package 60. As described above, the stack package 60 is thinner than the conventional stack package. The space between modules 200 is greater with the attached heat sink than the space between modules of the conventional stack package with an attached heat sink. Therefore, the problem of poor flow of air due to reduced space between the modules 200 is mitigated. Thus, the heat sink 207 may provide a good heat radiating characteristic without being hindered by a lack of air flow.

The heat sink 207 may be made of materials having a high heat conductivity, for example iron, aluminum, copper, ferrous alloy or copper alloy. The heat sink 207 may include a heat conductive member containing diamond or a heat pipe or a micro heat pipe having a phase change material (PCM). An adhesive attaching the heat sink 207 to the top surface of the stack package 60 may be a heat conductive adhesive 206. The heat conductive adhesive 206 may include an adhesive tape, thermal grease, an epoxy or a PCM type adhesive. The thickness of the heat conductive adhesive 206 may be about 0.5 mm or less, for establishing good heat conductivity.

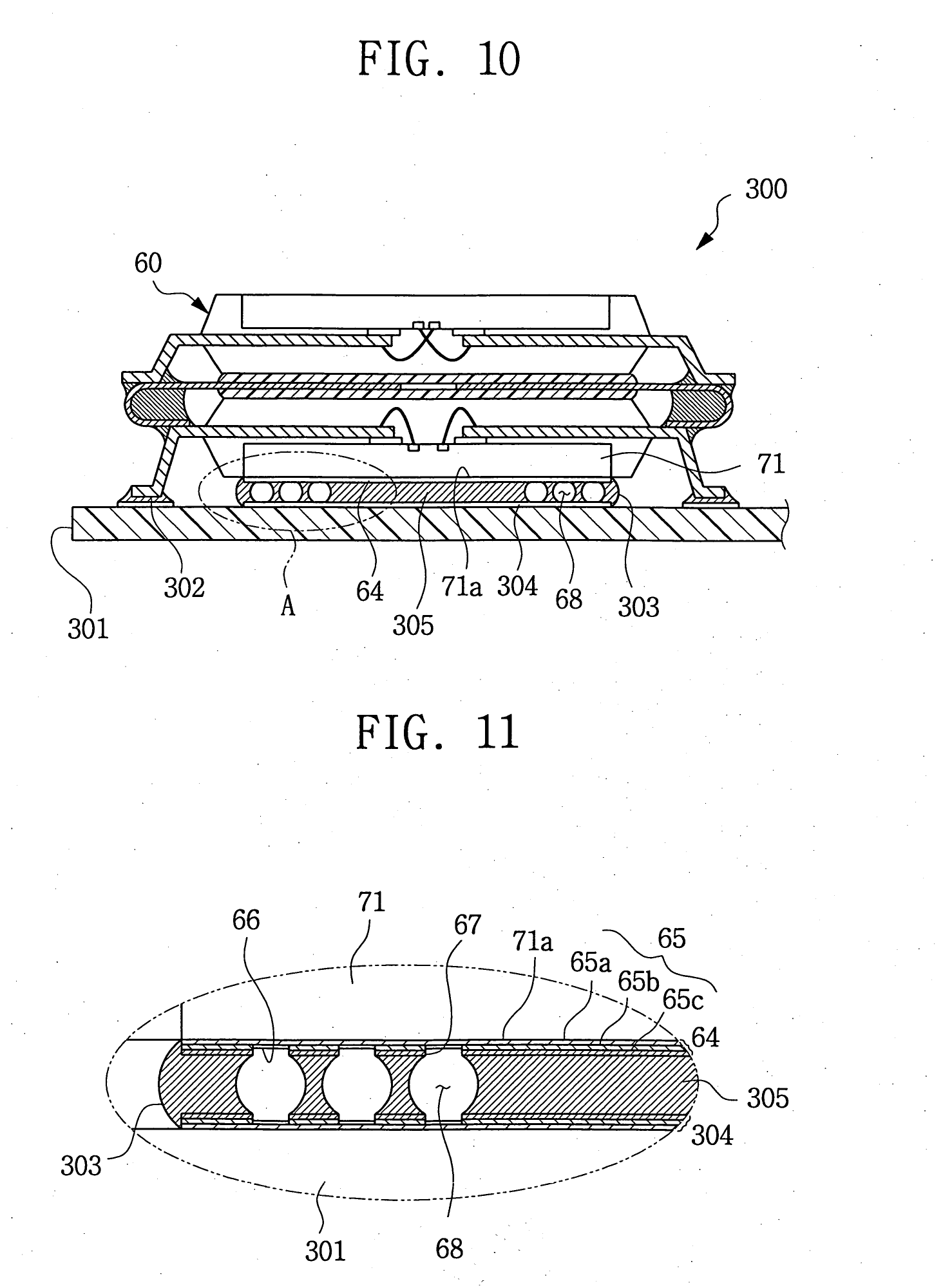

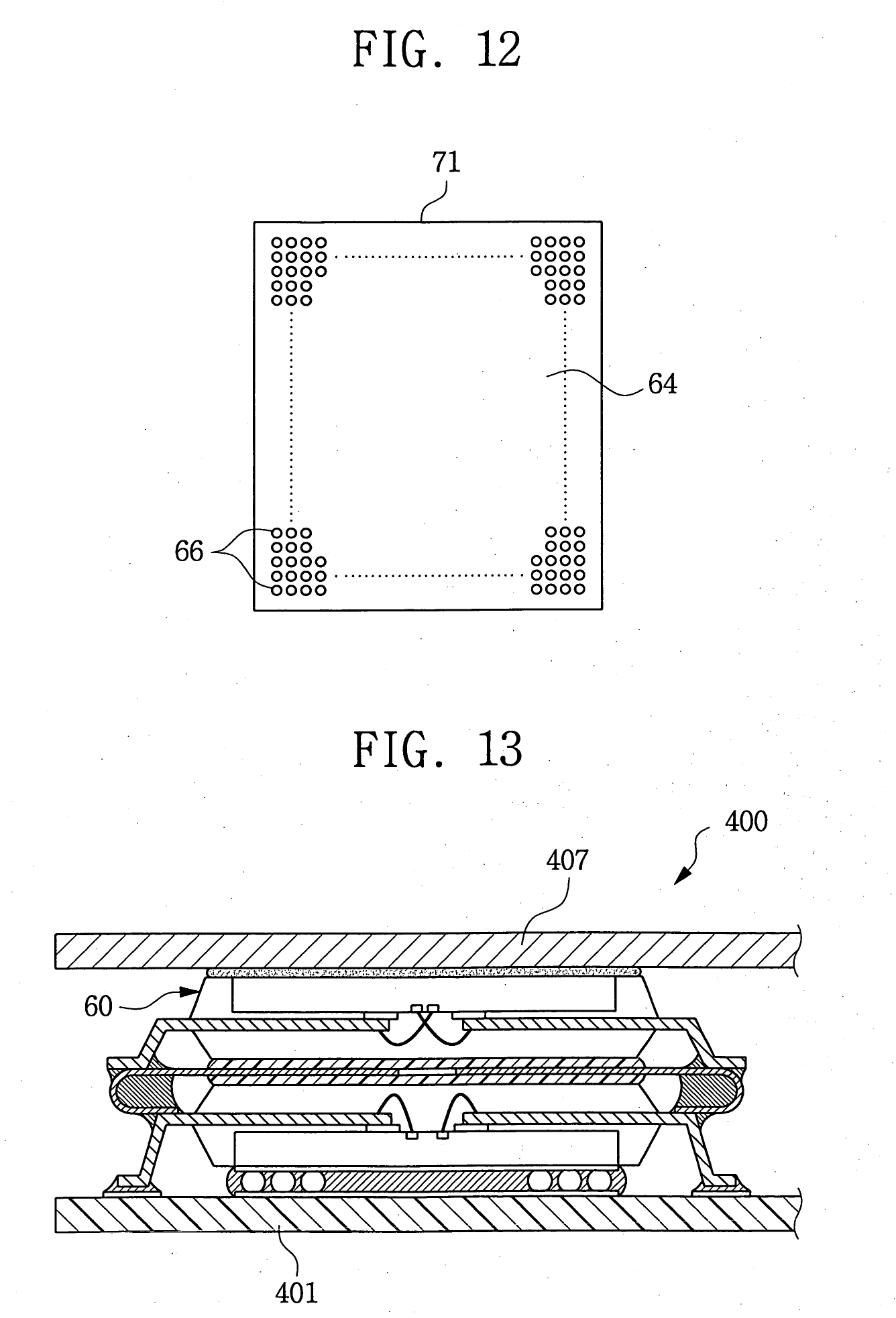

FIG. 10 is a cross-sectional view of a module 300 in accordance with a third embodiment of the present invention. FIG. 11 is an enlarged view of section A of FIG. 10. FIG. 12 is a bottom view of a first chip 71 of FIG. 10.

Referring to FIGS. 10 through 12, the module 300 comprises a module substrate 301 and a solder bonding portion 303. The stack package 60 is mounted on the module substrate 301. The solder bonding portion 303 is disposed between the bottom surface of the stack package 60 and the top surface of the module substrate 301. The solder bonding portion 303 is formed during a solder reflow process mounting the stack package 60 on the module substrate 301.

The formation of the solder bonding portion 303 may allow an improved heat radiation capability through the bottom surface of the stack package 60 as well providing a good solder bond between the stack package 60 and the module substrate 301.

The solder bonding portion 303 includes solder bonding layers 64 and 304 and a solder layer 305. The solder bonding layers 64 and 304 are arranged on the back surface 71a of the first chip 71 and the opposing top surface of the module substrate 301, respectively. The solder bonding layers 64 and 304 have solder wetting properties. The solder layer 305 is interposed between the solder bonding layers 64 and 304.

The solder bonding layer 64 on the back surface 71a of the first chip 71 has the same structure as the solder bonding layer 304 on the top surface of the module substrate 301. The solder bonding layer 64 includes a plurality of metal layers 65 and a void pad 66. The metal layers 65 may establish a good bond between the back surface 71a of the first chip 71 with the solder layer 305. The void pad 66 is formed in the metal layer 65 at a predetermined depth. The void 68 is created during forming of the solder bonding portion 303. The void 68 connects the void pad 66 of the solder bonding layer 64 with the opposing void pad of the solder bonding layer 304. The metal layer 65 includes a copper wiring layer 65a, a nickel plating layer 65b and a gold plating layer 65c. A void hole 67 is created by removing a portion of the nickel and gold plating layers 65b and 65c. The void pad 66 is formed on the bottom surface of the void hole 67. The void pad 66 may be made of a solder non-wettable material such as solder resist. Preferably, the void pads 66 are arranged at the periphery of the back surface 71a of the first chip 71.

The formation of the void 68 may be accomplished by using a flux containing solvent in a solder reflow process. Specifically, the solder reflow process may apply the flux containing solvent on the substrate pad 302 and the solder bonding layer 304 and followed by a solder paste thereon. Next, the stack package 60 is mounted on the module substrate 301. The reflow process is performed at a predetermined temperature to form the solder layer 305. When the solder layer 305 is formed, solvent contained in the flux is volatilized and gas is generated. The void is created around the solder non-wettable void pad 66. Solvent gas and remaining gas around the void pad 66 are absorbed in the created void. Therefore, a complete void 68 having a predetermined size is formed.

The void 68 of the solder bonding portion 303 may absorb thermal stresses which may occur due to the difference of the CTE of the module substrate 301 and the stack package 60. Therefore, it will help prevent weakened solder bonds between the stack packages 60 with the module substrate 301 from forming due to thermal stress.

FIG. 13 is a cross-sectional view of a module 400 in accordance with a fourth embodiment of the present invention. Referring to FIG. 13, the module 400 comprises a module substrate 401, a solder bonding portion and a heat sink 407. The stack package 60 is mounted on the module substrate 401. The heat sink 407 is attached to the top surface of the stack package 60. The solder bonding portion is disposed between the bottom surface of the stack package 60 and the top surface of the module substrate 401.

As fully described, a stack package and a module having the stack package mounted thereon according to the present invention have at least one of the following advantages.

First, back surfaces of first and second chips are exposed through the bottom and top surfaces of the stack package. This may allow improved heat radiation capability as well as reduced thickness of the stack package.

Further, because the thickness of the stack package is reduced, the attachment of a heat sink may not affect the space between modules. Therefore, it may prevent a poor flow of air due to reduced space between the modules. Besides, the heat sink may provide a good heat radiating characteristic.

Moreover, the formation of a solder bonding portion may allow a good solder bondability of the stack package with a module substrate as well as an improved heat radiation capability.

Although the preferred embodiments of the present invention have been described in detail hereinabove, it should be understood that many variations and/or modifications of the basic inventive concepts herein taught, which may appear to those skilled in the art, will still fall within the spirit and scope of the present invention as defined in the appended claims.

1. A stack package comprising:
a first package including:
a first package body having a top surface and a bottom surface;
a first chip having an active surface and a back surface; and
first outer leads protruding from the first package body and electrically connected to the first chip;
a second package including:
a second package body having a top surface and a bottom surface;
a second chip having an active surface and a back surface; and
second outer leads protruding from the second package body and electrically connected to the second chip,
wherein the second package is stacked over the first package; and
a flexible connection board interposed between the first and second packages and electrically connecting the first outer leads with the second outer leads,
wherein the first chip is disposed in the first package body such that the back surface of the first chip is exposed through the bottom surface of the first package.

2. The package of claim 1, wherein the first package includes:
a first chip having a plurality of first center pads on the active surface thereof;
first inner leads arranged along opposite sides of the active surface of the first chip with the first center pads therebetween;
first bonding wires respectively connecting the first center pads with the first inner leads;
wherein the first package body encapsulates the first chip, first inner leads and first bonding wires with a molding resin; and
first outer leads electrically connected to the first inner leads.

3. The package of claim 2, wherein the second package includes:
a second chip having a plurality of second center pads on the active surface thereof;
second inner leads arranged along opposite sides of the active surface of the second chip with the second center pads therebetween;
second bonding wires respectively connecting the second center pads with the second inner leads,
wherein the second package body encapsulates the second chip, second inner leads and second bonding wires with a molding resin; and
second outer leads electrically connected to the second inner leads,
wherein the second chip is disposed in the second package body such that the back surface of the second chip is exposed through the top surface of the second package.

4. The package of claim 3, wherein the first chip is substantially the same as the second chip.

5. The package of claim 2, wherein the first center pads are arranged on the active surface of the first chip along a first center line that runs substantially parallel to the edges of the active surface of the first chip, wherein the first center pads are cross-bonded to the corresponding inner leads.

6. The package of claim 3, when the second center pads are arranged on the active surface of the second chip along a second center line that runs substantially parallel to the edges of the active surface of the second chip, wherein the second center pads are cross-bonded to the corresponding inner leads.

7. The package of claim 2, wherein the first center pads are arranged in two lines on the active surface of the first chip, the two lines substantially parallel to the edges of the active surface of the first chip, and at least one of the first center pad is cross-bonded to the corresponding first inner lead.

8. The package of claim 7, wherein the first center pads are further arranged in an offset row formation.

9. The package of claim 3, wherein the second center pads are arranged in two lines on the active surface of the second chip, the two lines substantially parallel to the edges of the active surface of the second chip, and at least one of the second center pads is cross-bonded to the corresponding second inner lead.

10. The package of claim 9, wherein the second center pads are further arranged in an offset row formation.

11. A module comprising:
a module substrate having at least one stack package mounted on at least one surface thereof;
said at least one stack package comprising:
a first package including:
a first package body having a top surface and a bottom surface;
a first chip having an active surface and a back surface; and
first outer leads protruding from the first package body and electrically connected to the first chip;
a second package including:
a second package body having a top surface and a bottom surface;
a second chip having an active surface and a back surface; and
second outer leads protruding from the second package body and electrically connected to the second chip, the second package being stacked on the first package; and
a flexible connection board interposed between the first and second packages and electrically connecting the first outer leads with the second outer leads,
wherein the first chip is disposed in the first package body such that the back surface of the first chip is exposed through the bottom surface of the first package and the second chip is disposed in the second package body such that the back surface of the second chip is exposed through the top surface of the second package, and wherein the first outer leads are coupled to the module.

12. The module of claim 11, further comprising a solder bonding portion interposed between the bottom surface of at least one stack package and the surface of the module substrate.

13. The module of claim 12, wherein the solder bonding portion includes:
solder bonding layers formed on the back surface of the first chip and the top surface of the module substrate; and
a solder layer interposed between the solder bonding layers.

14. The module of claim 13, wherein the solder bonding portion further includes:
a first plurality of void pads formed in one of the solder bonding layers at a predetermined depth and a second plurality of void pads formed in a second of the solder bonding layers at a predetermined depth,
wherein voids are disposed between void pads of the first plurality of void pads and void pads of the second plurality of void pads.

15. The module of claim 14, wherein the solder bonding layer formed on the back surface of the first chip includes:
a copper pattern layer formed on the back surface of the first chip; and
a nickel or gold plating layer formed on the copper pattern layer,
wherein the nickel or gold plating layer has a plurality of holes, each hole of the plurality of holes adjacent to a void pad of the first plurality of void pads.

16. The module of claim 14, wherein the first plurality of void pads are arranged along a periphery of the first chip.

17. The module of claim 11, further comprising a heat sink attached to the top surface of the second package of the at least one stack package.

18. The module of claim 12, further comprising a heat sink attached to the top surface of the second package of the at least one stack package.

19. A stack package comprising:
a first package including:
a first package body having a top surface and a bottom surface;
a first chip having an active surface and a back surface; and
first outer leads protruding from the first package body and electrically connected to the first chip;
a second package including:
a second package body having a top surface and a bottom surface;
a second chip having an active surface and a back surface; and
second outer leads protruding from the second package body and electrically connected to the second chip,
wherein the second package is stacked over the first package; and
a flexible connection board interposed between the first and second packages and electrically connecting the first outer leads with the second outer leads,
wherein the second chip is disposed in the second package body such that the back surface of the second chip is exposed through the top surface of the second package.

20. The package of claim 1, wherein the first package includes:
a first chip having a plurality of first center pads on the active surface thereof;
first inner leads arranged along opposite sides of the active surface of the first chip with the first center pads therebetween;
first bonding wires respectively connecting the first center pads with the first inner leads;
wherein the first package body encapsulates the first chip, first inner leads and first bonding wires with a molding resin; and
first outer leads electrically connected to the first inner leads, wherein the first chip is disposed in the first package body such that the back surface of the first chip is exposed through the bottom surface of the first package.
